(19) United States
(12) Patent Application Publication
(10) Pub. No.: US 2010/0327433 A1
(43) Pub. Date: Dec. 30, 2010

(54) High Density MIM Capacitor Embedded in a Substrate

(75) Inventors: Fifin Sweeney, San Diego, CA (US); Mario Francisco Velez, San Diego, CA (US); Yuancheng Christopher Pan, San Diego, CA (US); Shiqun Gu, San Diego, CA (US)

Correspondence Address: QUALCOMM INCORPORATED, 5775 MOREHOUSE DR., SAN DIEGO, CA, 92121, US

(73) Assignee: QUALCOMM INCORPORATED, San Diego, CA (US)

(21) Appl. No.: 12/491,568

(22) Filed: Jun. 25, 2009

(51) Int. Cl. H01L 23/34; H01L 23/02; H01L 21/00

(52) U.S. Cl. 257/724; 257/678; 438/110; 257/E23.079; 257/E23.18; 257/E21.001

(57) ABSTRACT

An integrated circuit package includes a decoupling capacitor. The integrated circuit package also includes a packaging substrate. The decoupling capacitor is at least partially embedded in the packaging substrate. The integrated circuit package further includes a die mounted to the packaging substrate. The die is coupled to the decoupling capacitor. The die receiving substantially instantaneous current from the decoupling capacitor.

### TECHNICAL FIELD

The present disclosure generally relates to integrated circuits (ICs). More specifically, the present disclosure relates to packaging integrated circuits.

### BACKGROUND

Integrated circuits (ICs) are fabricated on wafers. Commonly, these wafers are semiconductor materials, for example, silicon. Through efforts of research and development, the size of the transistors making up the integrated circuits has decreased to 45 nm and soon will decrease further to 32 nm. As the transistors reduce in size, the voltage supplied to the transistors decreases. These voltages are smaller than the wall voltages available in most countries.

An integrated circuit is commonly coupled to a voltage regulator that converts available wall voltages to the lower voltages used by the integrated circuit. The voltage regulator ensures a predictable power supply is provided to the integrated circuit. This is an important function, because the ability of transistors to tolerate voltages under or over the target voltage is small. Only tenths of a volt lower may create erratic results in the integrated circuits; only tenths of a volt higher may damage the integrated circuits. As transistors of the integrated circuit turn on and off, the power load changes rapidly placing additional demand on the voltage regulator. The distance between the voltage regulator and the integrated circuit creates a long response time, preventing the voltage regulator from increasing power to the integrated circuit instantaneously, especially when the transistors switch on and off millions or billions of times each second. Decoupling capacitors provide additional stability to the power supplied to the integrated circuits.

Decoupling capacitors attached in close proximity to the integrated circuit provide instantaneous current to the integrated circuit. As demand on the power supply changes rapidly, the capacitor provides additional power and can refill at a later time when the power demand decreases. The decoupling capacitor allows integrated circuits to operate at the high frequencies and computational speeds desired by consumers. However, as the transistor sizes have decreased and transistor densities increased, finding area on the integrated circuit for decoupling capacitors has become difficult.

One configuration of decoupling the integrated circuit places decoupling capacitors directly on the die. This configuration occupies die area that could otherwise be used for active circuitry. Additionally, fabricating decoupling capacitors on the die involves additional manufacturing time that increases the cost of manufacturing.

As one example, a conventional decoupling capacitor used in integrated circuits is a thin film capacitor. Thin film capacitors may be fabricated on the substrate at an additional cost during manufacturing. These capacitors are typically alternating layers of a dielectric followed by a conductor.

Although the thin film capacitor is a simple structure, the capacitance is determined largely by the number of series capacitances in parallel. As more capacitance is added, the structure increases in height, which juxtaposes the shrinking size of the integrated circuits.

Metal-insulator-metal (MIM) capacitors may be manufactured to fit in smaller height constraints than thin film capacitors. When packaging the capacitors, height may be an important consideration. Furthermore, MIM capacitors offer additional flexibility over thin film capacitors in designing the equivalent series inductance (ESL) and equivalent series resistance (ESR) in a power distribution system.

As packages shrink in size to fit the smaller form factors present in mobile devices, space available on the package decreases. Additionally, as the circuits operate at higher frequencies, higher capacitances are required to ensure proper operation of the circuitry and transistors.

Thus, there is a need to provide instantaneous current to integrated circuits in a smaller package.

### BRIEF SUMMARY

According to one aspect of the disclosure, an integrated circuit package includes a decoupling capacitor at least partially embedded in a package substrate. The decoupling capacitor is adapted to be coupled to a die mounted to the packaging substrate.

According to another aspect of the disclosure, an integrated circuit package includes a packaging substrate. The integrated circuit package also includes a circuit mounted on the packaging substrate. The integrated circuit package further includes means for providing instantaneous current to the circuit. The means for providing being at least partially embedded in the packaging substrate.

According to a further aspect of the disclosure, a method of manufacturing an integrated circuit package includes at least partially embedding a capacitor in a package substrate. The method also includes coupling the capacitor to a structure coupled to a die mounted to the package substrate.

The foregoing has outlined rather broadly the features and technical advantages of the present disclosure in order that the detailed description that follows may be better understood. Additional features and advantages will be described hereinafter which form the subject of the claims of the disclosure. It should be appreciated by those skilled in the art that the conception and specific embodiments disclosed may be readily utilized as a basis for modifying or designing other structures for carrying out the same purposes of the present disclosure. It should also be realized by those skilled in the art that such equivalent constructions do not depart from the technology of the disclosure as set forth in the appended claims. The novel features which are believed to be characteristic of the disclosure, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 is a block diagram showing an exemplary wireless communication system in which an embodiment of the disclosure may be advantageously employed.

FIG. 2 is a block diagram illustrating a design workstation used for circuit, layout, and logic design of the disclosed semiconductor integrated circuit.

FIG. 3 is a block diagram illustrating a conventional integrated circuit package having a capacitor mounted on a surface.

FIG. 4 is a block diagram illustrating a conventional integrated circuit package having a capacitor and a stacked die.

FIG. 5 is a block diagram illustrating an embedded capacitor according to one embodiment.

FIG. 6 is a block diagram illustrating a packaging substrate having an embedded capacitor according to one embodiment.

FIG. 7 is a block diagram illustrating an interconnect to an embedded capacitor according to one embodiment.

FIG. 8 is a circuit schematic illustrating an equivalent circuit for a packaged integrated circuit having an embedded capacitor according to one embodiment.

### DETAILED DESCRIPTION

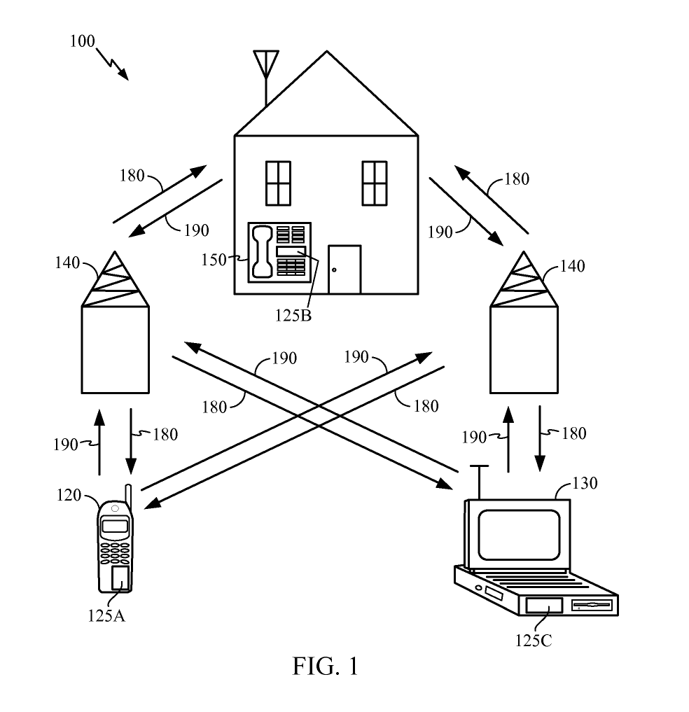

FIG. 1 is a block diagram showing an exemplary wireless communication system 100 in which an embodiment of the disclosure may be advantageously employed. For purposes of illustration, FIG. 1 shows three remote units 120, 130, and 150 and two base stations 140. It will be recognized that wireless communication systems may have many more remote units and base stations. Remote units 120, 130, and 150 include IC devices 125A, 125B and 125C, that include the disclosed packaging. It will be recognized that any device containing an IC may also include the packaging disclosed here, including the base stations, switching devices, and network equipment. FIG. 1 shows forward link signals 180 from the base station 140 to the remote units 120, 130, and 150 and reverse link signals 190 from the remote units 120, 130, and 150 to base stations 140.

In FIG. 1, remote unit 120 is shown as a mobile telephone, remote unit 130 is shown as a portable computer, and remote unit 150 is shown as a fixed location remote unit in a wireless local loop system. For example, the remote units may be mobile phones, hand-held personal communication systems (PCS) units, portable data units such as personal data assistants, GPS enabled devices, navigation devices, settop boxes, music players, video players, entertainment units, fixed location data units such as meter reading equipment, or any other device that stores or retrieves data or computer instructions, or any combination thereof. Although FIG. 1 illustrates remote units according to the teachings of the disclosure, the disclosure is not limited to these exemplary illustrated units. Embodiments of the disclosure may be suitably employed in any device which includes packaged integrated circuitry.

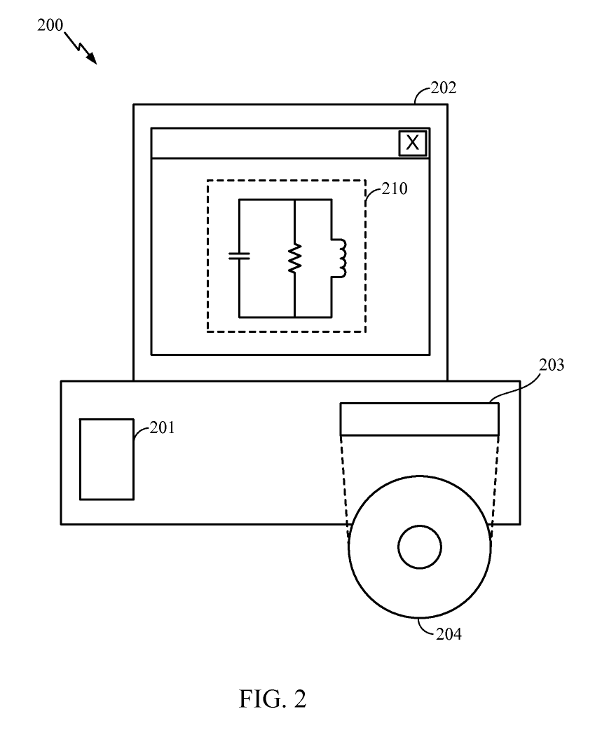

FIG. 2 is a block diagram illustrating a design workstation used for circuit, layout, and logic design of the disclosed semiconductor integrated circuit package. A design workstation 200 includes a hard disk 201 containing operating system software, support files, and design software such as Cadence or OrCAD. The design workstation 200 also includes a display to facilitate design of a circuit design 210. The circuit design 210 may be the packaging as disclosed below. A storage medium 204 is provided for tangibly storing the circuit design 210. The circuit design 210 may be stored on the storage medium 204 in a file format such as GDSII or GERBER. The storage medium 204 may be a CD-ROM, DVD, hard disk, flash memory, or other appropriate device. Furthermore, the design workstation 200 includes a drive apparatus 203 for accepting input from or writing output to the storage medium 204.

Data recorded on the storage medium 204 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 204 facilitates the design of the circuit design 210 by decreasing the number of processes for designing semiconductor ICs.

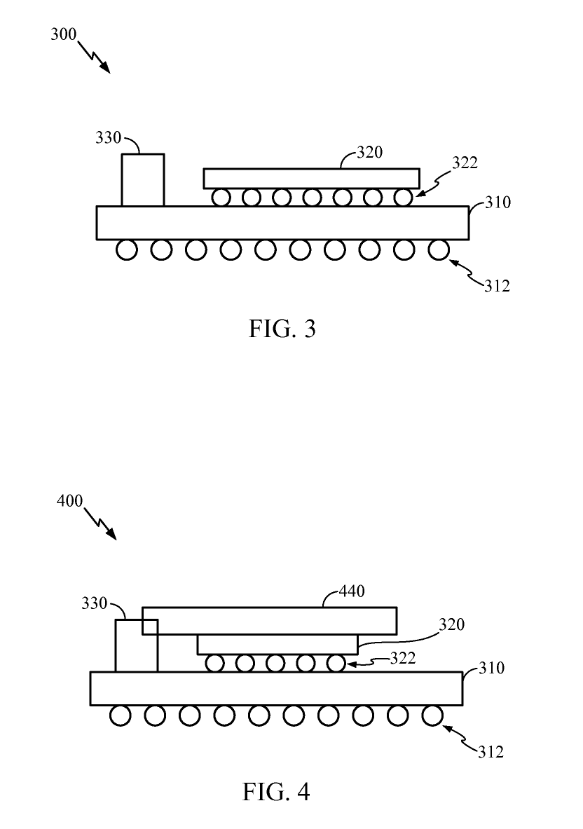

FIG. 3 is a block diagram illustrating a conventional integrated circuit package having a capacitor mounted on a surface. An integrated circuit package 300 includes a packaging substrate 310 having a ball grid array 312. The package 300 also includes a die 320 that includes integrated circuitry. The die 320 has a ball grid array 322 for coupling the die 320 to the packaging substrate 310. A thin film capacitor 330 is mounted on the packaging substrate 310. A capacitance of the thin film capacitor 330 is proportional to a height of the thin film capacitor 330.

The capacitor 330 consumes additional space on the packaging substrate 310 that could be used for additional dies that would create devices with additional functionality. Moreover, as will be shown below, the capacitor 330 consumes space that makes stacked dies difficult to produced on the packaging substrate 310.

FIG. 4 is a block diagram illustrating a conventional integrated circuit package having a capacitor and a stacked die. Stacked above the die 320 is a die 440. The die 320 may be a chipset and, the die 440 may be a memory device. As seen in the figure, stacking the dies 320, 440 leaves insufficient space for the capacitor 330. In order to fit, the capacitor 330 will be reduced in height or moved further from the dies 320 440. As discussed above, the capacitor should be located as close to circuitry as possible to effectively provide an instantaneous current. Reducing the height of the capacitor 330 may reduce the capacitance value to a level no longer sufficient for providing charge to the dies 320, 440 because the capacitance is proportional to height. These alternatives reduce the either the response time or the capacitance of capacitor 330, neither of which is desirable.

If the capacitor 330 is removed from the packaging substrate 310 the size of the packaging substrate 310 could be reduced. The resulting form factor of such a packaged integrated circuit could fit in a smaller device. Additionally, reducing the size of the packaging substrate 310 reduces materials cost. One solution to remove the capacitor 330 from the surface of the packaging substrate 310 is to embed the capacitor 330 in the packaging substrate 310.

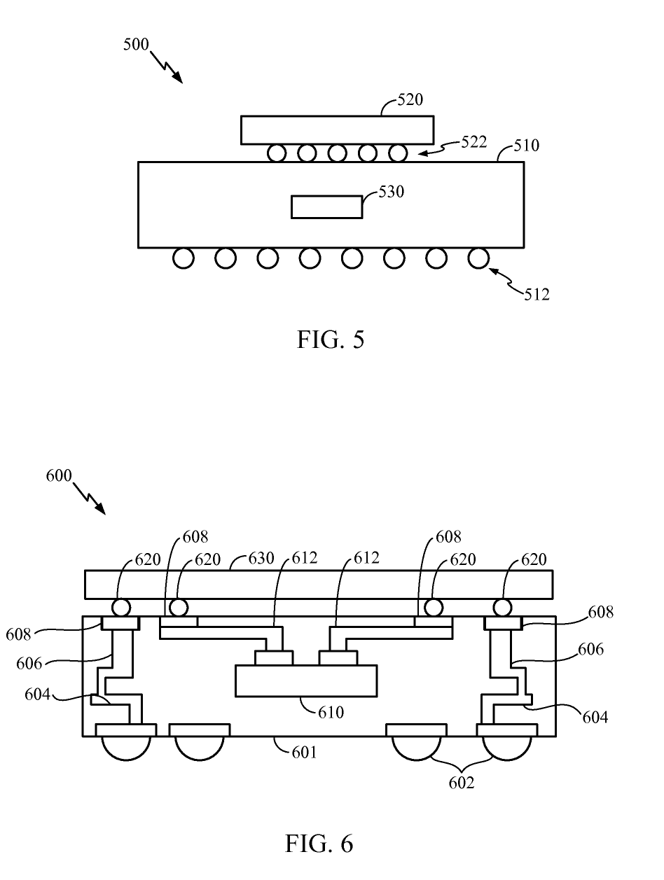

Embedding capacitors in the packaging substrate places capacitors close to the circuitry using instantaneous current and reduces height problems. FIG. 5 is a block diagram illustrating an embedded capacitor according to one embodiment. An integrated circuit package 500 includes a packaging substrate 510 having a ball grid array 512. Stacked on the packaging substrate 510 is a die 520 having a ball grid array 522. The ball grid array 522 couples the die 520 to the packaging substrate 510. The ball grid array 522 may be replaced by other packaging techniques such as a pin grid array. Embedded in the packaging substrate 510 is a capacitor 530. The capacitor 530 provides instantaneous current to the die 520 (specifically, to circuits disposed in the die) on the packaging substrate 510. The capacitor 530 may also provide instantaneous current for other dies stacked on the packaging substrate 510. The close location of the capacitor 530 to the die 520 allows current to be provided with a shorter response time than capacitors that may be located farther from the die 520.

Referring now to FIG. 6, a packaging substrate is illustrated. FIG. 6 is a block diagram illustrating a packaging substrate having an embedded capacitor according to one embodiment. A semiconductor package 600 includes a packaging substrate 601 having connectors such as a ball grid array 602. The ball grid array 602 couples to interconnects 604 inside the packaging substrate 601. The interconnects 604 may connect to vias 606 used to carry signals to a die 630 through connectors such as a pin or ball grid array 620 and a contact 608.

The packaging substrate 601 also includes an embedded capacitor 610. The capacitor 610 is embedded in the packaging substrate 601 and may be, according to one embodiment, a trench metal-insulator-metal (MIM) capacitor. A metal-insulator-metal capacitor includes an insulator layer coupled on one side with a first metal layer and on a second side with a second metal layer. Trench MIM capacitors offer higher capacitances than other capacitors because the total surface area, to which capacitance is proportional, includes not only the surface area covered by the capacitor but also the surface area of the sidewalls of the trenches. Interconnects 612 couple the capacitor 610 to circuitry (not shown) in the die 630 through the ball grid array 620 and the contact 608 to provide substantially instantaneous current when needed.

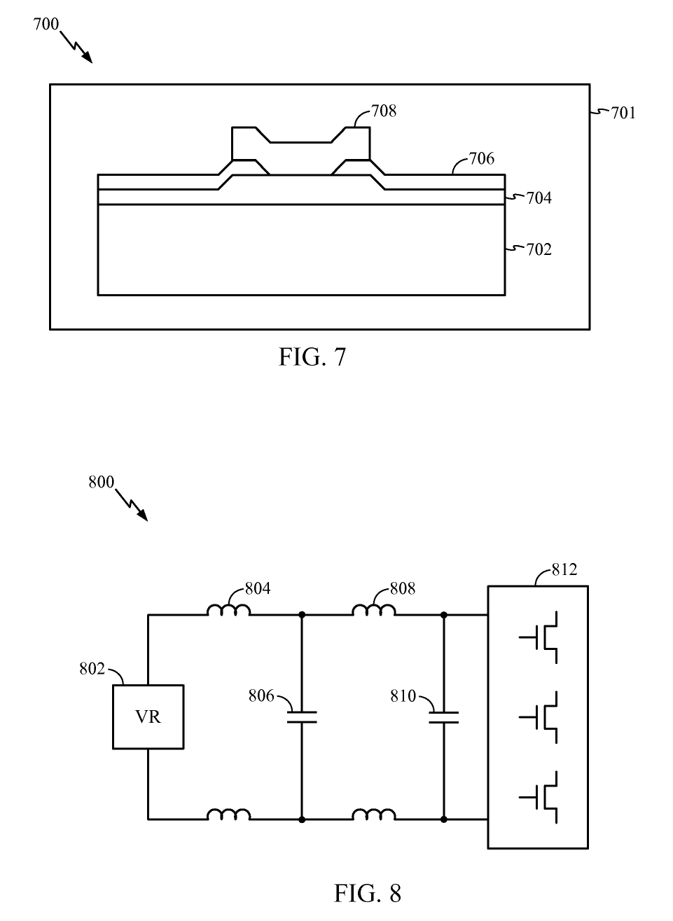

Turning now to FIG. 7, interconnects coupled to an embedded capacitor are illustrated according to one embodiment. A capacitor 702 is coupled to an interconnect 704. The capacitor 702 may be a trench MIM capacitor embedded in a packaging substrate 701 as described above. The interconnect 704 is partially covered by an insulator layer 706 that may be, for example, silicon oxide. Additionally, a bump 708 is coupled to the interconnect 704. The bump 708 may be, for example, copper for matching to copper metal traces and copper vias in the surrounding packaging substrate 701. The bump 708 couples the capacitor 702 to circuitry, which may be disposed in a die mounted on the packaging substrate 701. The bump 708 may also be, for example, a socket that couples to circuitry disposed in a die mounted on the packaging substrate 701 through a pin.

Decoupling capacitors are located near dies to provide substantially instantaneous current that compensates for inductance of interconnects and traces that couple circuitry to a voltage regulator. In an equivalent circuit, lines and traces may be represented by inductors and decoupling capacitors as capacitors. An equivalent circuit structure for an integrated circuit package having an embedded capacitor coupled to a circuit board is shown in FIG. 8, according to one embodiment. A voltage regulator 802 provides power to circuitry on a circuit board. The power is transmitted through printed traces on the circuit board to individual packaged integrated circuits. The printed traces have an inductance 804 proportional to the length of the trace. A capacitor having a capacitance 806 on the circuit board acts as a source of instantaneous current to counteract the inductance 804 of the trace. Interconnects in the individual packaged integrated circuit also have an inductance 808. A capacitor 810 embedded in the packaged integrated circuit provides substantially instantaneous current to a circuit 812, including for example, transistors, and counteracts a part of the inductance 808 of the interconnects. Although inductances other than the inductances 804, 808 may exist, they are small when compared to the inductances 804, 808.

Embedding decoupling capacitors in a packing substrate reduces parasitic inductances resulting from large distances between the decoupling capacitors and circuits for which they are providing instantaneous current. Additionally, trench MIM capacitors provide higher density capacitance than thin film capacitors built on the substrate. Furthermore, removing capacitors from the surface of the packaging substrate and embedding the capacitors in the packaging substrate reduces the form factor of the package.

Although specific circuitry has been set forth, it will be appreciated by those skilled in the art that not all of the disclosed circuitry is required to practice the disclosure. Moreover, certain well known circuits have not been described, to maintain focus on the disclosure.

Although the present disclosure and its advantages have been described in detail, it should be understood that various changes, substitutions and alterations can be made herein without departing from the technology of the disclosure as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. An integrated circuit package, comprising:
a decoupling capacitor at least partially embedded in a packaging substrate;
wherein the decoupling capacitor is adapted to be coupled to a die mounted to the packaging substrate.

2. The integrated circuit package of claim 1, in which the decoupling capacitor comprises an insulator layer separating a first metal layer and a second metal layer.

3. The integrated circuit package of claim 2, in which the decoupling capacitor comprises a trench in which the insulator layer and the first metal layer and the second metal layer partially reside.

4. The integrated circuit package of claim 1, in which the decoupling capacitor is completely embedded in the packaging substrate.

5. The integrated circuit package of claim 1, in which the decoupling capacitor is coupled to the die by an interconnect coupled to a bump above the packaging substrate.

6. The integrated circuit of claim 1 in which the die receives substantially instantaneous current from the decoupling capacitor.

7. The integrated circuit package of claim 1, in which the die comprises a microprocessor.

8. The integrated circuit package of claim 1, further comprising interconnects configured to couple the die to the decoupling capacitor.

9. The integrated circuit package of claim 8, further comprising a contact configured to couple the die to the decoupling capacitor.

10. The integrated circuit package of claim 9, further comprising a packaging connection configured to couple the die to the decoupling capacitor.

11. An integrated circuit package, comprising:
a packaging substrate;
a circuit mounted on the packaging substrate; and
means for providing instantaneous current to the circuit, the means for providing being at least partially embedded in the packaging substrate.

12. The integrated circuit package of claim 11, in which the means for providing instantaneous current is completely embedded in the packaging substrate.

13. The integrated circuit package of claim 12, further comprising means for coupling the circuit to the means for providing instantaneous current.

14. A method of manufacturing an integrated circuit package, the method comprising:
at least partially embedding a capacitor in a package substrate; and
coupling the capacitor to a structure coupled to a die mounted to the package substrate.

15. The method of claim 14, in which the capacitor provides substantially instantaneous current to the die.

16. The method of claim 14, in which the capacitor is completely embedded in the package substrate.

17. The method of claim 14, in which the coupling comprises coupling to a bump of a ball grid array.

18. The method of claim 14, in which the coupling comprises coupling to a pin of a pin grid array.
